(19) United States
(12) Patent Application Publication
(10) Pub. No.: US 2010/0170443 A1
(43) Pub. Date: Jul. 8, 2010

(54) FILM MANUFACTURING DEVICE

(75) Inventor: SHAO-KAI PEI, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/639,141

(22) Filed: Dec. 16, 2009

(30) Foreign Application Priority Data
Jan. 5, 2009 (CN) 200910300041.1

(51) Int. Cl. C23C 16/02

(52) U.S. Cl. 118/726

(57) ABSTRACT

A film manufacturing device for forming a film on a substrate includes a vaporizing device, a container, an absorption tower and a film deposition device. The vaporizing device is configured for vaporizing a dopant containing solution. The container is configured for containing a film forming solution. The absorption tower is configured for mixing the film forming solution with the vaporized dopant containing solution to obtain a precursor solution. The film deposition device is configured for forming the film on the substrate using the precursor solution.

### BACKGROUND

1. Technical Field

The present disclosure relates to film manufacturing technology, and particularly, to a film manufacturing device.

2. Description of Related Art

In a commonly used film manufacturing process, a film forming solution and a dopant containing solution are directly mixed to make a precursor solution. The precursor solution is then deposited on a substrate to form a film thereon.

However, the precursor solution produced thusly is not well-mixed and is often unstable, resulting in deterioration of the obtained film.

Therefore, a film manufacturing device which can overcome the described shortcomings is desirable.

### BRIEF DESCRIPTION OF THE DRAWINGS

FIG. 1 is a schematic view of a film manufacturing device, according to an exemplary embodiment.

FIG. 2 is similar to FIG. 1, but showing that a zinc oxide film doped with aluminum is formed using the film manufacturing device of FIG. 1.

FIG. 3 is an electron microscopy scan of the zinc oxide film doped with aluminum from FIG. 2.

### DETAILED DESCRIPTION

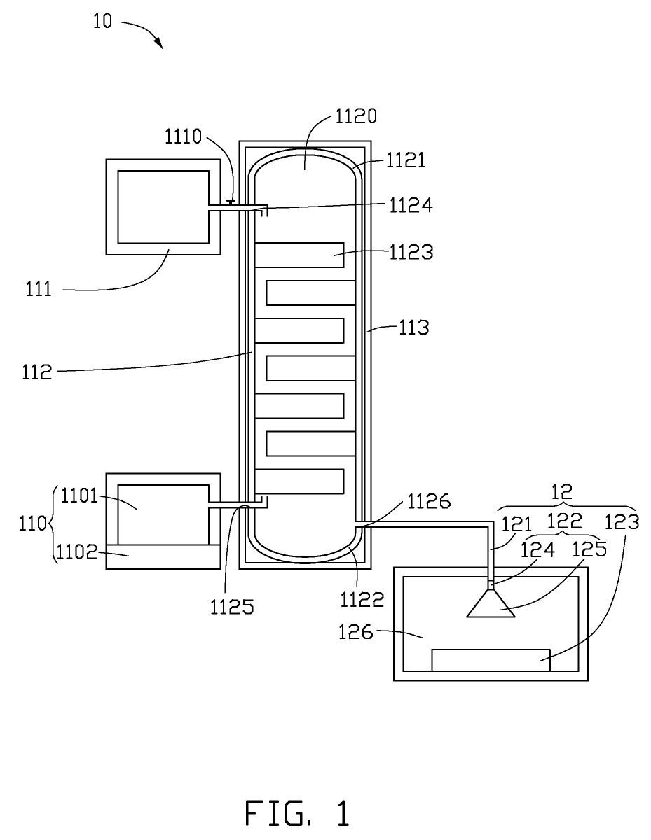

Referring to FIG. 1, a film manufacturing device 10 for forming a film on a substrate, according to an exemplary embodiment, includes a vaporizing device 110, a container 111, an absorption tower 112, a microwave heater 113 and a film deposition device 12.

The vaporizing device 110 is configured for vaporizing a dopant containing solution. In this embodiment, the vaporizing device 110 includes a receiving chamber 1101 and a heater 1102. The dopant containing solution is received in the receiving chamber 1101. The receiving chamber 1101 communicates with the absorption tower 112. The heater 1102 is configured for heating the dopant containing solution received in the receiving chamber 1101 to vaporize the dopant containing solution.

The container 111 is configured for containing a film forming solution to the absorption tower 112. The container 111 includes a valve 1110 configured for adjusting an amount of the film forming solution entering the absorption tower 112.

The absorption tower 112 is configured for mixing the film forming solution with the vaporized dopant containing solution to obtain a precursor solution. In this embodiment, the absorption tower 112 is a panel absorption tower. The absorption tower 112 includes an absorption chamber 1120 and a plurality of plates 1123 received therein. The absorption chamber 1120 includes a top portion 1121 and a bottom portion 1122. The plates 1123 are positioned in the absorption chamber 1120 between the top portion 1121 and the bottom portion 1122. The plate 1123 is configured for uniformly mixing the film forming solution with the vaporized dopant containing solution. The plate 1123 is a perforated plate. A diameter of the hole defined in the plate 1123 is about 3-8 millimeters (mm) The absorption chamber 1120 includes a first entry 1124 arranged adjacent to the top portion 1121. The first entry 1124 communicates with the container 111 and is configured for introducing the film forming solution into the absorption chamber 1120. The absorption chamber 1120 includes a second entry 1125 and an exit 1126 arranged adjacent to the bottom portion 1122. The second entry 1125 communicates with the receiving chamber 1101 and is configured for introducing the vaporized dopant containing solution into the absorption chamber 1120. Accordingly, when the film forming solution and the vaporized dopant containing solution both enter the absorption chamber 1120, the film forming solution flows downward and the vaporized dopant containing solution rises. The vaporized dopant containing solution is divided into a plurality of gas flows by the perforated plate 1123 so that the liquid film forming solution is well mixed with the gas dopant containing solution to obtain a precursor solution. The precursor solution is then collected at the bottom portion 1122 of the absorption chamber 1120. The exit 1126 communicates with the film deposition device 12 and is configured for introducing the obtained precursor solution into the film deposition device 12.

The microwave heater 113 sleeves the absorption tower 112 and is configured for heating the precursor solution for easily depositing the film on the substrate.

The film deposition device 12 is configured for forming the film on the substrate using the precursor solution. The film deposition device 12 includes a guide pipe 121, a nozzle 122 and a heating platform 123.

The guide pipe 121 is connected to the exit 1126 of the absorption chamber 1120 and is configured for guiding the precursor solution to the nozzle 122.

The nozzle 122 is configured for applying the precursor solution from the guide pipe 121 onto the substrate. The nozzle 122 includes a connecting end 124 and an injection end 125 opposite to the connecting end 124. The connecting end 124 is connected to the guide pipe 121. The injection end 125 faces the heating platform 123. A cross-section of the injection end 125 is larger than that of the connecting end 124.

The heating platform 123 is configured for supporting and heating the substrate thereon. The nozzle 122 and the heating platform 123 are placed inside an airtight depositing chamber 126 to avoid pollution of the precursor solution in the environment.

In other alternative embodiments, the film deposition device 12 may further include a ultrasonic atomization unit. The ultrasonic atomization unit may be arranged between the guide pipe 121 and the nozzle 122 to atomize the precursor solution to improve uniformity of the obtained film on the substrate.

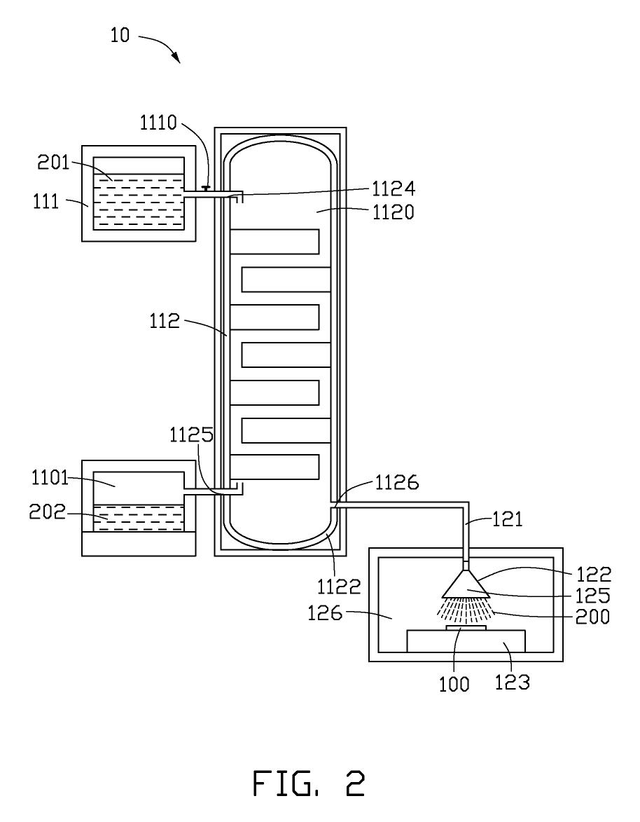

Referring to FIG. 2, a schematic view of an example of a zinc oxide film doped with aluminum manufactured with the film manufacturing device of FIG. 1 is shown. In the example, steps S100 through S106 are included.

In step S100, a film forming solution 201 and a dopant containing solution 202 are provided.

The film forming solution 201 is ethanol solution with zinc acetate of 0.09 moles per liter and is contained in the container 111. The dopant containing solution 202 is ethanol solution with aluminum chloride and is received in the receiving chamber 1101. The aluminum chloride content depends on the aluminum content doped in the obtained zinc oxide film.

In step S 102, a substrate 100 is placed on the heating platform 123 and heated.

The substrate 100 can be metal, glass, silicon wafer, ceramic, or other. In this example, the substrate 100 is an aluminum oxide substrate. The substrate 100 is heated to a temperature of about 320° C.

In step S104, the dopant containing solution 202 is vaporized and the vaporized dopant containing solution 202 enters the absorption tower 112 from the second entry 1125, and the valve 1110 is opened to introduce the film forming solution 201 into the absorption tower 112 from the first entry 1124, whereby a precursor solution is obtained and collected at the bottom portion 1122 of the absorption chamber 1120.

The dopant containing solution 202 is heated to a temperature of about 110° C. and is vaporized. The vaporized dopant containing solution 202 enters the absorption chamber 1120 from the second entry 1125. Meanwhile, the film forming solution 201 flows into the absorption chamber 1120 from the first entry 1124. The gas dopant containing solution 202 and the liquid film forming solution 201 are well mixed in the absorption chamber 1120 for about 1 hour. The precursor solution 200 is obtained and collected at the bottom portion 1122. The precursor solution 200 flows out of the absorption chamber 1120 through the exit 1126.

In step S 106, the precursor solution 200 is guided to the film deposition device 12 to form a film on the heated substrate 100.

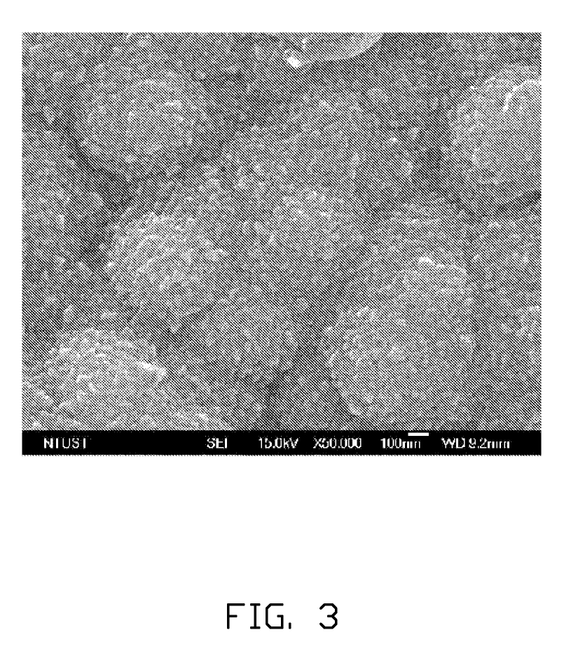

The precursor solution 200 is guided by the guide pipe 121 to the nozzle 122 and injected into the heated substrate 100 through the injection end 125 of the nozzle 122. The precursor solution 200 is oxidized in the depositing chamber 126 so that a zinc oxide film doped with aluminum is formed on the substrate 100. Referring to FIG. 3, as seen in an electron microscopy scan of the zinc oxide film doped with aluminum from the experiment, the phase state of the zinc oxide film doped with aluminum is uniform.

Since the liquid film forming solution 201 and the gas dopant containing solution 202 are well mixed in the absorption tower 112, the obtained precursor solution 200 is stable and uniformity of the obtained film coated on the substrate 100 is enhanced.

It is to be understood, however, that even though numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A film manufacturing device for forming a film on a substrate, comprising:
a vaporizing device configured for vaporizing a dopant containing solution;
a container configured for containing a film forming solution;
an absorption tower configured for mixing the film forming solution with the vaporized dopant containing solution to obtain a precursor solution; and
a film deposition device configured for forming the film on the substrate using the precursor solution.

2. The film manufacturing device of claim 1, wherein the vaporizing device comprises a receiving chamber and a heater, the receiving chamber communicating with the absorption tower and configured for receiving the dopant containing solution, and the heater configured for heating the dopant containing solution to vaporize the dopant containing solution received in the receiving chamber.

3. The film manufacturing device of claim 1, wherein the absorption tower comprises an absorption chamber and a plurality of plates; the absorption chamber comprises a top portion and a bottom portion, the plates positioned in the absorption chamber and between the top portion and the bottom portion, and configured for uniformly mixing the film forming solution with the vaporized dopant containing solution.

4. The film manufacturing device of claim 3, wherein the absorption tower comprises a first entry arranged adjacent to the top portion, a second entry and an exit arranged adjacent to the bottom portion, the first entry communicating with the container and configured for introducing the film forming solution into the absorption chamber, the second entry communicating with the vaporizing device and configured for introducing the vaporized dopant containing solution into the absorption chamber, the exit communicating with the film deposition device and configured for introducing the precursor solution into the film deposition device.

5. The film manufacturing device of claim 4, wherein the film deposition device comprises a guide pipe, a nozzle and a heating platform, the guide pipe connected to the exit and configured for guiding the precursor solution to the nozzle, the nozzle configured for applying the precursor solution onto the substrate, the heating platform configured for supporting and heating the substrate thereon.

6. The film manufacturing device of claim 5, wherein the nozzle comprises a connecting end and an injection end, the connecting end connected to the guide pipe, the injection end facing the heating platform.

7. The film manufacturing device of claim 1, further comprising a microwave heater, the microwave heater sleeving the absorption tower and configured for heating the precursor solution.
